(19) United States
(12) Patent Application Publication
(10) Pub. No.: US 2010/0159136 A1
(43) Pub. Date: Jun. 24, 2010

(54) STATIC CHEMICAL VAPOR DEPOSITION OF y-Ni + y'-Ni3AI COATINGS

(75) Inventors: Kang N. Lee, Zionsville, IN (US); Michael Cybulsky, Indianapolis, IN (US); Wiliam J. Brindley, Indianapolis, IN (US)

Correspondence Address: SHUMAKER & SIEFFERT, P. A., 1625 RADIO DRIVE, SUITE 300, WOODBURY, MN, 55125, US

(73) Assignee: Rolls-Royce Corporation, Indianapolis, IN (US)

(21) Appl. No.: 12/641,060

(22) Filed: Dec. 17, 2009

Related U.S. Application Data
(60) Provisional application No. 61/139,330, filed on Dec. 19, 2008.

(51) Int. Cl. C23C 16/12; C23C 16/44

(52) U.S. Cl. 427/255.39; 427/255.28

(57) ABSTRACT

A static chemical vapor deposition (CVD) process may be used to deposit a coating including a γ-Ni+γ′-Ni₃Al phase constitution over a substrate. A static CVD process is performed in a closed system that may include the substrate, and coating material and an activator. The γ-Ni+γ′-Ni₃Al coating may be modified by one or more additional elements, including, for example, Hf, Y, Zr, Ce, La, Si, Cr, Pt, or additional elements present in the substrate. A static CVD process may include co-deposition of two or more elements, and may also include sequential static CVD steps, each of which is performed in a closed system.

This application claims priority from U.S. Provisional Application Ser. No. 61/139,330 filed Dec. 19, 2008, the entire content of which is incorporated herein by reference.

### TECHNICAL FIELD

The disclosure generally relates to techniques for forming a coating on a substrate.

### BACKGROUND

The components of high-temperature mechanical systems, such as, for example, gas-turbine engines, must operate in severe environments. For example, the high-pressure turbine blades and vanes exposed to hot gases in commercial aeronautical engines typically experience metal surface temperatures of about 900-1000° C., with short-term peaks as high as 1150° C.

To reduce the surface temperatures experienced by these components, many of the components of high-temperature mechanical systems may be coated with a thermal barrier coating (TBC). The TBC typically includes a ceramic material such as, for example, yttria-stalizied zirconia (YSZ). The YSZ layer may be deposited on the component as a porous layer to provide strain tolerance for the thermal expansion and contraction experienced by the TBC. However, the transparency of the YSZ layer to oxygen transport imposes the requirement that the surface of the component is coated with a coating that protects the component from oxidation attack.

For example, the surface of the component may be coated with a bond coat, which includes sufficient Al to form a protective thermally grown oxide (TGO) of aluminum oxide on the surface of the bond coat. The bond coat may include a γ-Ni+γ′-Ni₃Al phase constitution, which matches the phase constitution of the superalloy substrate. In addition to providing oxidation resistance, the bond coat bonds the TBC to the component. In some embodiments, the γ-Ni+γ′-Ni₃Al coating may also be used as a stand-alone coating that protects the substrate from oxidation.

### SUMMARY

In general, the present disclosure is directed to forming a coating including a γ-Ni+γ′-Ni₃Al phase constitution over a substrate. The coating may include Ni and Al, and in some embodiments, may further include additional elements, such as, for example, Hf, Y, Zr, Ce, La, Si, Cr, or additional elements present in the substrate. The coating may be formed over the substrate using a static chemical vapor deposition (static CVD) process, which occurs in a closed system, as will be described in further detail herein. In some embodiments, the coating further includes Pt, which is deposited in a separate step from the static CVD process. In some embodiments, the coating may be formed over the substrate using two or more sequential static CVD steps.

In one aspect, the present disclosure is directed to a method that includes depositing a Pt-group metal over a substrate. The method also includes heating with a closed retort the substrate and a composition comprising Al, a reactive element, and a halide activator to a sufficient temperature to form a vapor phase aluminum halide and a reactive element halide. The Al comprises sufficient Al to form a coating comprising a γ-Ni+γ′-Ni₃Al phase constitution of the substrate, and the composition is substantially free of filler. The method may further include depositing sufficient Al and reactive element over the substrate to form the coating comprising the γ-Ni+γ′-Ni₃Al phase constitution.

In another aspect, the present disclosure is directed to a method that includes depositing a Pt-group metal over a substrate and heating within a closed retort the substrate and a first composition comprising Al to form a first vapor phase that deposits the Al over the substrate. The first composition is substantially free of filler. The method also includes heating within the closed retort the substrate and a second composition comprising a reactive element to form a second vapor phase that deposits the reactive element over the substrate. The second composition is also substantially free of filler. An amount of Al and an amount of reactive element deposited on the substrate is sufficient to form a coating comprising a γ-Ni+γ′-Ni₃Al phase constitution.

The techniques of the present disclosure may provide advantages. For example, a static CVD process may utilize a retort that is simpler and less expensive than a conventional CVD process. In particular, static CVD utilizes a closed retort or other chamber. In contrast, conventional CVD apparatuses include a retort in which the article to be coated is placed, and further require a separate device that heats the coating materials to form a coating gas, which is then directed into the retort using a piping structure. The complexity of a conventional CVD apparatus results in a higher cost than the apparatus utilized in the presently-described static CVD techniques.

Static CVD techniques may also provide enhanced flexibility compared to a pack cementation process. Specifically, pack cementation is a co-deposition process, in which all elements, compounds, or alloys which are deposited on an article are contained in the pack and deposited in a single coating step. In contrast, static CVD techniques may utilize co-deposition of two or more elements, compounds or alloys, but may also utilize sequential deposition, in which one or more elements, compounds or alloys are deposited in a first coating step, and one or more elements, compounds or alloys, which may include similar or different elements, compounds or alloys deposited in the first coating step, are deposited in a second coating step. This may increase the process window and process robustness.

Static CVD processes also do not require use of filler, in contrast to pack cementation processes. This may reduce the amount of material necessary. In some cases, a static CVD process may utilize substantially no filler.

Additionally, static CVD may be used to coat an interior cavity of an article.

Further, the static CVD apparatus may be portable.

The details of one or more embodiments of the invention are set forth in the accompanying drawings and the description below. Other features, objects, and advantages of the invention will be apparent from the description and drawings, and from the claims.

### BRIEF DESCRIPTION OF DRAWINGS

FIGS. 1A and 1B are block diagrams which illustrate an example system for depositing over a substrate a coating including a γ-Ni+γ′-Ni₃Al phase constitution.

FIG. 2 is a flow diagram illustrating an example technique of depositing a coating including a γ-Ni+γ′-Ni₃Al phase constitution.

FIG. 3 is a cross-sectional diagram of an article including a Pt-group metal layer.

FIG. 4 is a cross-sectional diagram of an article including a layer comprising Al deposited over a Pt-group metal layer.

FIG. 5 is a flow diagram illustrating another example technique of depositing a coating including a γ-Ni+γ′-Ni₃Al phase constitution.

FIG. 6 is a block diagram which illustrates an example system for depositing over a substrate a first layer of a coating.

FIG. 7 is a block diagram which illustrates an example system for depositing over a substrate a second layer of a coating.

FIG. 8 is a cross-sectional micrograph of an example Pt- and Hf-modified γ-Ni+γ′-Ni₃Al coating following thermal cycling.

### DETAILED DESCRIPTION

In general, the present disclosure is directed to forming a coating including a γ-Ni+γ′-Ni₃Al phase constitution (a γ-Ni+γ′-Ni₃Al coating) over a substrate. The coating may include Ni and Al, and in some embodiments, may further include additional elements, such as, for example, Hf, Y, Zr, Ce, La, Si, Cr, or additional elements present in the substrate. As used herein, an unmodified γ-Ni+γ′-Ni₃Al coating includes substantially only Ni and Al, while a modified γ-Ni+γ′-Ni₃Al coating includes other elements in addition to Ni and Al. The γ-Ni+γ′-Ni₃Al coating may be formed over the substrate using a static chemical vapor deposition (static CVD) process, which occurs in a closed system, as will be described in further detail herein. In some embodiments, the γ-Ni+γ′-Ni₃Al coating further includes a Pt-group metal, such as Pt, Pd, Ir, Rh and Ru, or combinations thereof, which is deposited over the substrate in a separate step from the static CVD process. In some embodiments, the γ-Ni+γ′-Ni₃Al coating may be formed over the substrate using two or more sequential static CVD steps, may be formed by co-deposition of two or more elements in a single static CVD step, or both.

As used herein, a γ-Ni+γ′-Ni₃Al phase constitution refers to an alloy or coating including a Ni phase (the γ-Ni phase) and a Ni₃Al phase (the γ′-Ni₃Al phase). In some embodiments, the coating may consist essentially of a γ-Ni+γ′-Ni₃Al phase constitution. That is, the coating may include small amounts of other phases (e.g., no greater than about 5 vol. %), such as, for example, β-NiAl. In other embodiments, the coating may consist of a γ-Ni+γ′-Ni₃Al phase constitution, and may include essentially no other phases, including β-NiAl.

A γ-Ni+γ′-Ni₃Al coating may include, for example, less than about 30 at. % Al, less than about 30 at. % of a Pt-group metal, less than about 30 at. % Cr, less than about 15 at. % Si, less than about 2 at. % of at least one reactive element, such as Hf, Y, La Cr or Zr, less than about 15 at. % Co, less than about 15 at. % Ti, Re, W, Ta, Mo, and the like, and the balance Ni. In some embodiments, a γ-Ni+γ′-Ni₃Al coating may include about 10 at. % to about 23 at. % Al, about 10 at. % to about 25 at. % of a Pt-group metal, about 2 at. % to about 20 at. % Cr, about 1 at. % to about 9 at. % Si, about 0.2 at. % to about 2 at. % of a reactive element, such as Hf, Y, La, Cr or Zr, about 5 at. % to about 10 at. % Co, less than about 10 at. % Ti, Re, W, Ta, Mo, and the like, and the balance Ni.

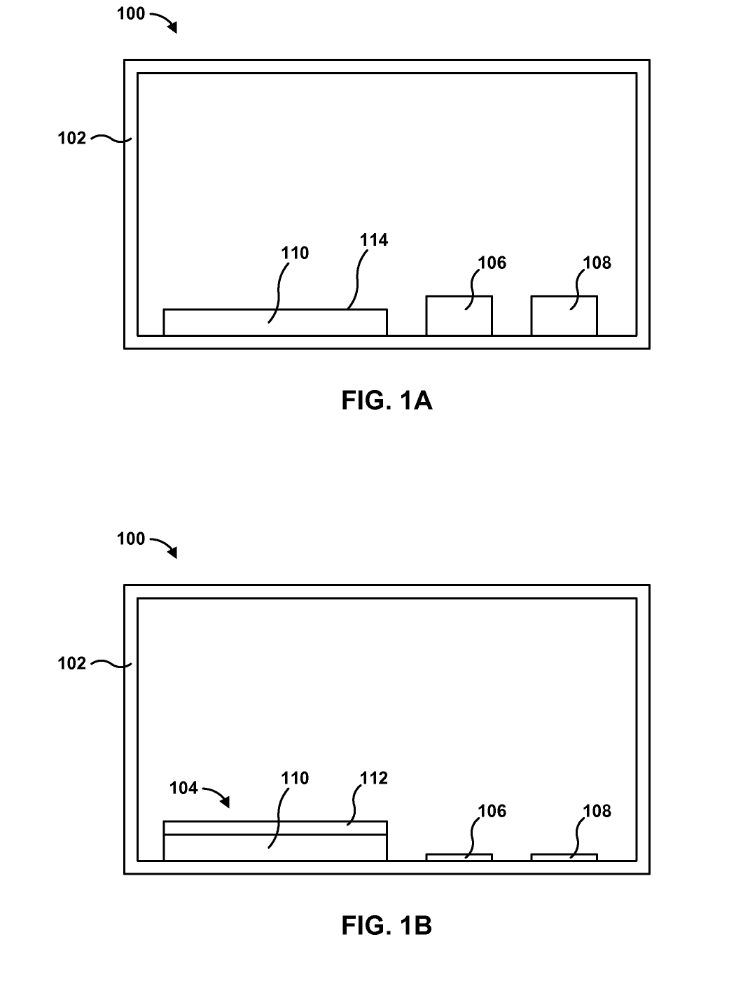

FIG. 1A is a conceptual block diagram illustrating a coating system 100 including a closed retort 102, a substrate 110, a coating material (or donor) 106 and an activator 108. Coating system 100 may be used to deposit coating 112 over substrate 110 to form a coated article 104 using static chemical vapor deposition (static CVD), as illustrated in FIG. 1B. As used herein, static CVD refers to a CVD process in which each coating step is performed in a closed system; that is, a system in which no material (e.g., mass) input or output occurs after beginning the coating step. For example, as shown in FIG. 1, closed retort 102 encloses substrate 110, coating material 106 and activator 108. Immediately prior to commencement of the static CVD step, coating material 106 and activator 108 each include sufficient material to form the desired coating 112 over substrate 110; no further coating material 106 or activator 108 is input into or output from closed retort 102 while the static CVD step is performed. A static CVD coating process may include one or more static CVD step, and coating material 106 and/or activator 108 may be added or removed from retort 102 before commencement or after completion of a static CVD step. However, each static CVD step is performed in a closed system.

As used herein, “deposited over” or “formed over” is defined as a layer or coating that is deposited or formed on top of another layer or coating, and encompasses both a first layer or coating deposited or formed immediately adjacent a second layer or coating and a first layer or coating deposited or formed on top of a second layer or coating with one or more intermediate layer or coating present between the first and second layers or coatings. In contrast, “deposited directly on” or “formed directly on” denotes a layer or coating that is deposited or formed immediately adjacent another layer or coating, i.e., there are no intermediate layers or coatings.

Closed retort 102 may be any furnace or other heating chamber capable of heating substrate 110, coating material 106 and activator 108 to temperatures used in the static CVD process. In addition, in some embodiments, retort 102 may include a fluid inlet and a fluid outlet that allow retort 102 to be purged of air and backfilled with an inert gas prior to heating. For example, in some embodiments, retort 102 may be purged of air using a vacuum pump and filled with argon. Retort 102 may then be purged of the argon with the vacuum pump and filled with fresh argon. This process may be performed one or more times to limit the concentration of oxygen in retort 102.

Substrate 110 may include a Ni- or Co-based superalloy, such as, for example, those available from Martin-Marietta Corp., Bethesda, Md., under the trade designation MAR-M247; those available from Cannon-Muskegon Corp., Muskegon, Mich., under the trade designation CMSX-4 and CMSX-10; and the like. Substrate 110 typically includes a γ-Ni+γ′-Ni₃Al phase constitution.

Coating material 106 may include one or more elements, alloys, or compounds that are to be deposited over substrate 110 to form coating 112. For example, coating material 106 may include an Al source. The Al source may include elemental Al, or may include elemental Al or an Al alloy, such as, for example, (by weight) 55Al:45Cr, 30Al:70Cr, other Al—Cr alloys, Al alloys with other elements, or the like.

In some embodiments, coating material 106 may include other elements, alloys or compounds which modify properties of coating 112, such as, for example oxidation resistance, hot corrosion resistance, aluminum oxide formation rate, extent of γ-Ni or γ′-Ni₃Al phase constitution, or the like. For example, coating material 106 may include at least one reactive element. The addition of a reactive element may stabilize the γ′ phase of coating 112. In some embodiments, the reactive element may include at least one of Hf, Y, Zr, La and Ce. Thus, if sufficient reactive metal is added to the composition, the resulting phase constitution may comprise a majority γ′-Ni₃Al, or even solely γ′-Ni₃Al. Further, the addition of a reactive element may decrease the growth rate of aluminum oxide scales, and may also improve aluminum oxide scale adherence to coating 112.

In some embodiments, coating material 106 may also include Si or Cr. Cr may be added to coating material 106 to produce a coating 112 having improved oxidation and hot corrosion resistance compared to a coating 112 without Cr, while Si may improve hot corrosion resistance. Coating 112 may also include a Pt-group metal, such as Pt, Pd, Ir, Rh and Ru, or combinations thereof, which may be deposited in a separate coating step, as will be described in further detail below. In some embodiments, coating 112 may further include one or more elements present in substrate 110, such as, for example, Cr, Co, Ti, Mo, Re, Ta, W, or the like.

In embodiments in which coating material 106 includes more than one element and/or compound, coating material 106 may include an alloy of the elements and/or compounds. Alternatively, closed retort 102 may enclose two or more separate coating materials 106, each of which is a separate physical source for one or more of the elements and/or compounds. For example, coating material 106 may include an Al—Cr alloy, as described above, which may be a physical source for both Al and Cr. As another example, a first coating material 106 may include a first physical source for a first coating element (e.g., Al) and a second coating material 106 may include second physical source for a second coating material (e.g., Cr). Continuing the example, the first and second physical sources may be physically separate from each other within retort 102.

Coating material 106 may be a powder or other solid source, such as a block or pellet, of the coating elements and/or compounds. For example, coating material 106 may include an Al—Cr alloy that has been ground into powder form, may include an Al—Cr alloy in block or pellet form, or may comprise a block, pellet, or powder of an elemental or compound (e.g., Al).

Activator 108 may include a halide species that reacts with coating material 106 to form a donor-halogen compound (e.g., a halide of a donor, such as AlCl₃). The donor-halogen compound may be formed from a solid-gas reaction between solid coating material 106 and a gas phase activator 108, which has sublimated or evaporate. The donor-halogen compound may also be formed by a gas phase reaction between coating material 106 that has evaporated or sublimated and activator 108, which has also evaporated or sublimated. For example, in embodiments in which coating material 106 includes Al, the halide species may react with the Al and form a gas phase aluminum halide. The gas phase aluminum halide may then diffuse to a surface 114 of substrate 110, where the Al may react with the surface, deposit on surface 114 in coating 112, and liberate the halogen. The halogen is then free to react with another atom or molecule of coating material 106 to form another donor-hologen compound.

Similarly, a reactive element such as Hf may react with the halide species to form a hafnium halide, Cr may react with the halide species to form a chromium halide, or Si may react with the halide species to form a silicon halide.

In some embodiments, the activator may include NH₄Cl, HCl, (NH₄)HF₂, or another halide salt.

In some embodiments, coating material 106 and activator 108 may not be separate, but may instead include a solid donor-halogen compound. For example, the donor-halogen compound may include a solid aluminum halide, such as AlCl₃, a reactive element halide, a silicon halide, or a chromium halide. The solid donor-halogen compound may be a powder, pellet, block, or the like.

As illustrated in FIGS. 1A and 1B, coating material 106 and activator 108 may not be in contact with substrate 110. This may facilitate the use of static CVD to coat a surface of an interior cavity of an article, such as, for example, a turbine blade or vane. In some embodiments, the vapor phase donor-halogen compound may be directed to the interior cavity of the article by an apparatus, such as a piping system or the like.

In addition, coating material 106 and activator 108 may be substantially free of any filler material. In the present disclosure, substantially free of filler means including less than about 1 wt. % filler. In some embodiments, coating material 106 and activator 108 may be essentially free of filler, which in the present disclosure indicates coating material 106 and activator 108 include no more than trace amounts of filler (e.g., an amount present in commercial available coating material 106 or activator 108). In contrast, other coating techniques, such as pack cementation, may utilize large amounts of filler, such as, for example, a majority of filler with minority amounts of coating material 106 and activator 108. In this way, static CVD may require less material and produce less waste than other coating techniques.

In practice, a static CVD step includes providing an article to be coated (e.g., substrate 110), coating material 106 and activator 108 in retort 102. Retort 102 may be evacuated of air with a vacuum pump and filled with an inert gas, such as, for example argon. Retort 102 is then heated to heat substrate 110, coating material 106 and activator 108. For example, retort 102 may be heated to a temperature of less than about 2100° F. (about 1150° C.) for less than about 20 hours. As other examples, retort 102 may be heated to a temperature of about 1400° F. to about 1800° F. (about 760° C. to about 982° C.) for about 1 hour to about 20 hours, or retort 102 may be heated to a temperature of about 1500° F. to about 1700° F. (about 815° C. to about 925° C.) for about 1 hour to about 6 hours.

During the heating of retort 102, at least some of activator 108, and in some embodiments coating material 106, evaporate or sublimate to a vapor phase. The coating material 106 and activator 108 then react to form a donor-halogen compound, which may diffuse to surface 114 of substrate 110. The donor in the donor-halogen compound may react with and deposit over substrate 110, which liberates the halogen in the donor-halogen compound. The halogen is then free to react with another donor to form another donor-halogen compound and continue the coating process.

Because substrate 110 is heated with coating material 106 and activator 108, the donor in coating 112 may diffuse into substrate 110 and elements present in substrate 110 may diffuse into coating 112 during the static CVD process. In some embodiments, this may result in coating 112 including a γ-Ni+γ′-Ni₃Al phase constitution upon completion of the static CVD process. In other embodiments, substrate 110 and coating 112 may be exposed to a subsequent heat treatment to produce or homogenize the γ-Ni+γ′-Ni₃Al phase constitution, as will be described in further detail below.

By controlling the time and temperature at which the static CVD process is performed, the composition of coating material 106, and the amount of activator 108 that is present in retort 102, the composition of coating 112, and thus the phase constitution, may be controlled. For example, increasing the time or temperature of the static CVD process, increasing the Al content in coating material 106, or increasing the amount of activator 108 present in a static CVD step that deposits Al in coating 112, may increase the amount of Al in coating 112. Conversely, decreasing the time or temperature of the static CVD process, decreasing the Al content in coating material 106, or decreasing the amount of activator 108 present in a static CVD step that deposits Al in coating 112, may decrease the amount of Al in coating 112. Increasing an amount of Al in coating 112 may result in a larger proportion of γ′-Ni₃Al phase, while decreasing an amount of Al in coating 112 may result in a larger proportion of γ-Ni phase. The precise time range, temperature range, composition of coating material 106 and amount of activator 108 that result in a specific amount of Al and phase constitution may depend on a surface area of substrate 110 and a size of retort 102.

As one example, a two-step static CVD process may be used to deposit a coating on a CMSX-4 substrate. The first static CVD step may include a coating material 106 comprising a 30Al:70Cr alloy, an activator 108 comprising about 40 grams of NH₄Cl, and a heating to about 1532° F. (about 833° C.) for about 6 hours. the second static CVD step may include a coating material 106 comprising 30Al:70Cr, an activator 108 comprising about 40 grams of NH₄Cl, a second coating material 106/activator 108 comprising about 50 grams HfCl₄, and a heating to about 1532° F. (about 833° C.) for about 2 hours. The resulting coating 112 may include about 19 at. % Al, about 22 at. % Pt, about 18 at. % Cr, about 6.5 at. % Co, about 0.35 at % Hf, about 1.2 at. % Ti, about 0.4 at. % Re, about 1.5 at. % W, about 2 at. % Ta, about 0.6 at. % Mo, and the balance Ni.

As described briefly above, coating 112 may include a γ-Ni+γ′-Ni₃Al phase constitution. In some embodiments, other phases may be present, such as, for example, β-NiAl. In other embodiments, coating 112 may consist essentially of a γ-Ni+γ′-Ni₃Al phase constitution, i.e., may include no more than about 5 vol. % of other Ni and/or NiₓAl_{y} phases, such as, for example, β-NiAl. In yet other embodiments, coating 112 may consist of a γ-Ni+γ′-Ni₃Al phase constitution and be essentially free of other phases (e.g., may include no more than trace amounts of other phases).

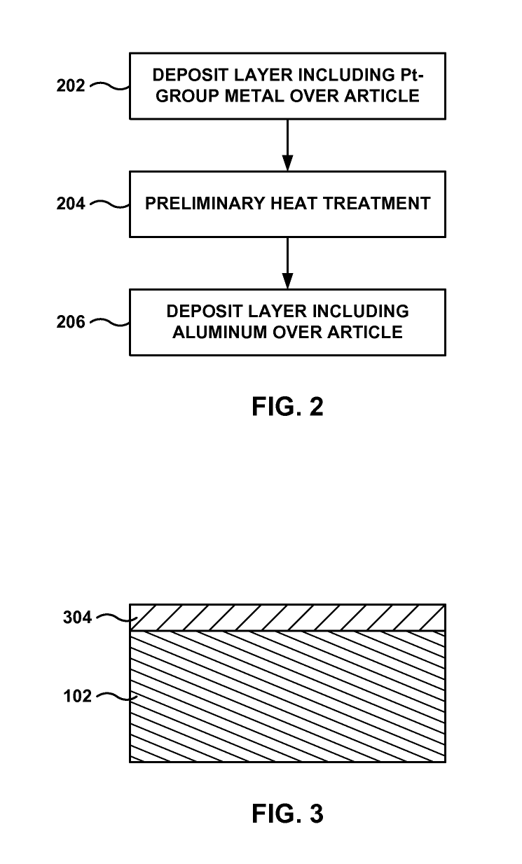

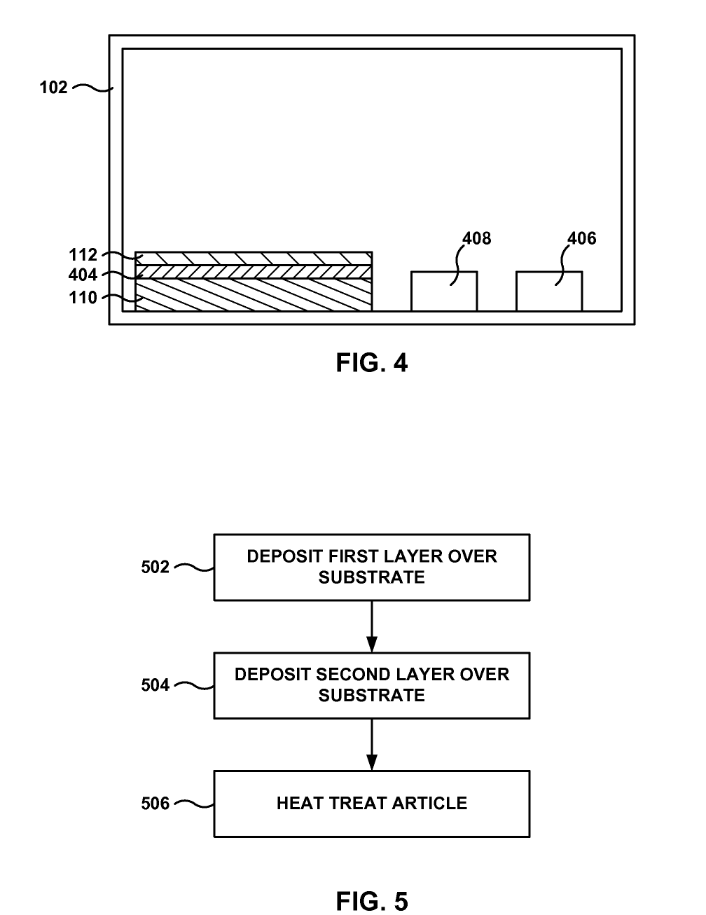

FIG. 2 is a flow diagram illustrating an example technique of forming over a substrate a coating including a γ-Ni+γ′-Ni₃Al phase constitution, which will be described with further reference to FIGS. 3 and 4. First, a layer 304 including a Pt-group metal may be deposited over substrate 110 (202). The Pt-group metal may be selected from, for example, Pt, Pd, Ir, Rh, Ru, and combinations thereof. In some embodiments, Pt may be preferred. The Pt-group metal may be deposited by any conventional technique, such as, for example, electrodeposition, and in some embodiments, may include a thickness of about 5 micrometers to about 7 micrometers.

Substrate 110 and layer 304 including the Pt-group metal may then undergo a preliminary heat treatment (204). The preliminary heat treatment may facilitate interdiffusion between layer 304 and substrate 110. For example, Ni and Al present in substrate 110 may diffuse into layer 304, while the Pt-group metal in layer 304 may diffuse into substrate 110. This may result in a Pt-enriched surface region 404, as shown in FIG. 4. The Pt-enriched surface region 404 may also include elements present in the substrate, such as, for example, Ni, Al, Cr, Co, Ti, Mo, Re, Ta, W, and the like.

In some embodiments, the preliminary heat treatment may include heating substrate 110 and layer 304 to a temperature of about 1000° C. (about 1832° F.) to about 1200° C. (about 2192° F.) for about 1 hour to about 5 hours. In other embodiments, the preliminary heat treatment may include heating substrate 110 and layer 304 to a temperature of about 1100° C. (about 2012° F.) to about 1150° C. (about 2100° F.) for about 1 to about 3 hours.

In some embodiments, the preliminary heat treatment also results in the diffusion of Al present in substrate 110 into Pt-enriched surface region 404. When Al diffuses into Pt-enriched surface region 404 in sufficient amounts, a γ-Ni+γ′-Ni₃Al phase constitution may result. However, in some embodiments, an amount of Al that diffuses into Pt-enriched surface region 404 may be insufficient to form a γ-Ni+γ′-Ni₃Al phase constitution after the preliminary heat treatment.

Once the preliminary heat treatment is completed, substrate 110, which includes Pt-enriched surface region 404, may be placed in a retort 102 and coating 112, which includes Al, may be deposited over substrate 110 (206). Coating 112 may be deposited using static CVD, as described above. Specifically, an Al source 406 and a halide compound 408 may be placed in retort 102 along with substrate 110. Alternatively, a solid aluminum halide may be used instead of separate Al source 406 and halide compound 408. Air in retort 102 may then be evacuated using a vacuum pump and retort 102 may be filled with an inert gas, such as, for example, argon.

Similar to the description of FIGS. 1A and 1B, Al source 406 may include elemental Al, or an Al alloy, such as, for example, (by weight) 55Al:45Cr, 30Al:70Cr, other Al—Cr alloys, Al alloys with other elements, or the like. Halide compound 408 may include, for example, NH₄Cl, HCl, (NH₄)HF₂, or another halide salt. Al source 406 and halide compound 408 may include powder, pellets, a block of solid material, or the like. In some embodiments, Al source 406 and halide compound 408 may not be separate, and may instead be an aluminum-halogen compound, such as, for example, AlCl₃.

Retort 102 may then be heated to initiate the static CVD process by evaporating or sublimating at least some of the Al source 406 and halide compound 408. As described above in further detail, the gaseous halide and Al may react to form an aluminum halide, which diffuses to a surface of substrate 110 (e.g., a surface of Pt-enriched surface region 404), where the Al reacts with the surface and is deposited over substrate 110 in coating 112. The reaction of the Al with the surface of substrate 110 liberates the halogen, which is free to react with another Al atom to form another aluminum halide.

As described above, static CVD may also be used to deposit other elements, such as, for example, Cr, Si, a reactive element including Hf, Y, Zr, La or Ce, or the like. The additional elements may modify properties of coating 112, such as, for example, oxidation resistance, hot corrosion resistance, aluminum oxide scale formation rate, extent of γ-Ni+γ′-Ni₃Al phase constitution, or the like. In some embodiments, these elements may be co-deposited with Al in the same static CVD step, and may also be present in retort 102. As described above, the additional elements may be present in halide compounds (e.g., HfCl₄), and may be present in Al source 406, or be present as a separate source or separate sources.

Because the static CVD process occurs at a relatively high temperature, interdiffusion between substrate 110, Pt-enriched surface region 404 and coating 112 may occur during the static CVD process. For example, Al and other elements deposited in coating 112 may diffuse into Pt-enriched surface region 404, while elements present in Pt-enriched surface region 404 may diffuse into coating 112. This may result in a γ-Ni+γ′-Ni₃Al phase constitution in the resulting coating 112.

Once coating 112 has been deposited over substrate 110, the entire article 410 may optionally be subject to a post-deposition heat treatment step to further interdiffuse the elements in coating 112 and Pt-enriched surface region 404 and homogenize the resultant coating. The post-deposition heat treatment may include heating article 410 to a temperature of about 1000° C. (about 1832° F.) to about 1200° C. (about 2192° F.) for about 1 hour to about 5 hours, or a temperature of about 1100° C. (about 2012° F.) to about 1150° C. (about 2100° F.) for about 1 hour to about 3 hours. The post-deposition heat treatment may be carried out in an inert atmosphere, such as vacuum or argon.

Pt may reduce the thermodynamic activity of Al in the coating 112. In fact, sufficient Pt content may reduce the thermodynamic activity of Al in coating 112 below the activity of Al in substrate 110, which may cause Al to diffuse up its concentration gradient from substrate 110 into coating 112. This may reduce and/or substantially eliminate Al depletion from Pt-enriched surface region 404, which may reduce spallation of an aluminum oxide scale formed on coating 112, increase the stability of the aluminum oxide scale layer, and increase the useful life of the coating 112.

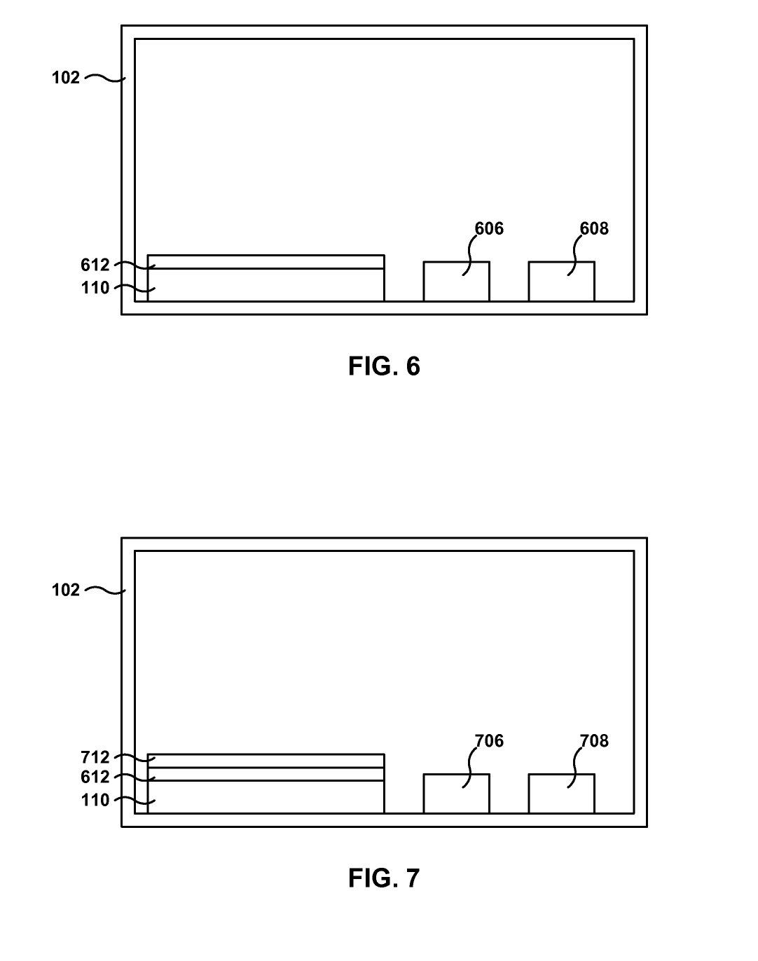

In some embodiments, a static CVD process including sequential static CVD steps may be used to deposit multiple layers of a coating, as shown in the flow diagram of FIG. 5 and block diagrams of FIGS. 6 and 7. Each static CVD step in a sequential static CVD process may including deposition of a single element, or may include co-deposition of two or more elements. Static CVD processes including combinations of co-deposition and sequential deposition may further increase the flexibility of the static CVD processes and result in a larger process window for the static CVD processes. For example, Al may be deposited in a first static CVD process, followed by deposition of Hf is a second static CVD process, or vice versa. As other examples, Al may be deposited in a first static CVD process, followed by co-deposition of Al and Hf in a second static CVD process, or Hf may be deposited in a first static CVD process, followed by co-deposition of Al and Hf in a second static CVD process. Because Hf and Al deposition is competitive, applying Al in the first static CVD process, followed by co-deposition of Al and Hf may facilitate the formation of γ-Ni+γ′-Ni₃Al coatings including increased Al content while incorporating Hf. As another example, a static CVD process including sequential deposition or a combination of sequential deposition and co-deposition may facilitate formation of γ-Ni+γ′-Ni₃Al coatings including a high level of Cr (e.g., greater than about 10 at. % Cr), and may utilize donor materials including a high Cr content, such as 30Al:70Cr.

First, substrate 110 is placed in retort 102 and a first layer 612 is deposited over substrate 110 from a first coating source 606 using a first activator 608 in a first static CVD step 600 (502). First coating source 606 may include one or more coating material, including, for example, Al, Cr, Si, a reactive element including Hf, Y, Zr, La, Ce, or the like. As described above, the one or more coating material may also be present in separate physical coating sources. In some embodiments, first coating source 606 and first activator 608 may not be separate, and may instead be a donor halide compound, such as, for example, AlCl₃, HfCl₄, or the like.

The first static CVD step 600 may be performed at a temperature of about 1400° F. to about 1800° F. (about 760° C. to about 982° C.) for about 1 hour to about 20 hours, or a temperature of about 1500° F. (about 815° C.) to about 1700° F. (about 925° C.) for about 1 hours to about 6 hours, preferably under an inert atmosphere, as described above. Also described above, because of the relatively high temperature used for first static CVD step 600, some elements present in substrate 110, such as, for example, Co, Ti, Mo, Re, Ta, W, or the like, may diffuse from substrate 110 to first layer 612.

Once first layer 612 has been deposited, a second layer 712 may be deposited in a second static CVD step 700. Second layer 712 is deposited from second coating source 706 using second activator 708 within retort 102, which may be the same retort 102 used in first static CVD step 600, or may be a different retort 102.

Second coating source 706 may include one or more coating elements, such as, for example, Al, Cr, Si, a reactive element including Hf, Y, Zr, La, Ce, or the like. In some embodiments, second coating source 706 may include at least one coating element different from first coating source 606. For example, as described above, first coating source 606 may include Al and second coating source 706 may include both Al and Hf. When second coating source includes two or more elements, the elements may be formed in an alloy, mixture, or other combination, or may include separate physical sources, as described in further detail above.

Second static CVD step 700 may be performed under an inert atmosphere, similar to described above, and may be carried out at a temperature of about 1400° F. to about 1800° F. (about 760° C. to about 982° C.) for about 1 hour to about 20 hours, or at a temperature of about 1500° F. (about 815° C.) to about 1700° F. (about 925° C.) for about 1 hours to about 6 hours. Second static CVD step 700 may result in interdiffusion of elements from substrate 110, first layer 612 and second layer 712. In some embodiments, a coating 714 including a γ-Ni+γ′-Ni₃Al phase constitution results from the interdiffusion that occurs during second static CVD step 700.

Whether or not a γ-Ni+γ′-Ni₃Al coating 714 results from second static CVD step 700, coated article 704 may be exposed to a post-deposition heat treatment (506). The post-deposition heat treatment may cause further diffusion within coating 714 to form a γ-Ni+γ′-Ni₃Al phase constitution and/or produce a more homogenous coating 714.

### EXAMPLE

### Example 1

A γ-Ni+γ′-Ni₃Al coating was prepared on a super alloy substrate using static CVD. The super alloy substrate was placed in a closed retort with an Al—Cr alloy aluminum source and a solid NH₄Cl activator. The super alloy substrate, aluminum source and activator were heated to about 1532° F. for about 6 hours to deposit a layer of aluminum over the substrate.

The aluminum-coated substrate was then placed in a retort with a solid HfCl₄ hafnium source/activator, an Al—Cr alloy aluminum source and a solid NH₄Cl activator. The contents of the retort were heated to about 1532° F. for about 2 hours to co-deposit the Hf and Al on the aluminum-coated substrate to form the coating having a Pt- and Hf-modified γ-Ni+γ′-Ni₃Al phase constitution.

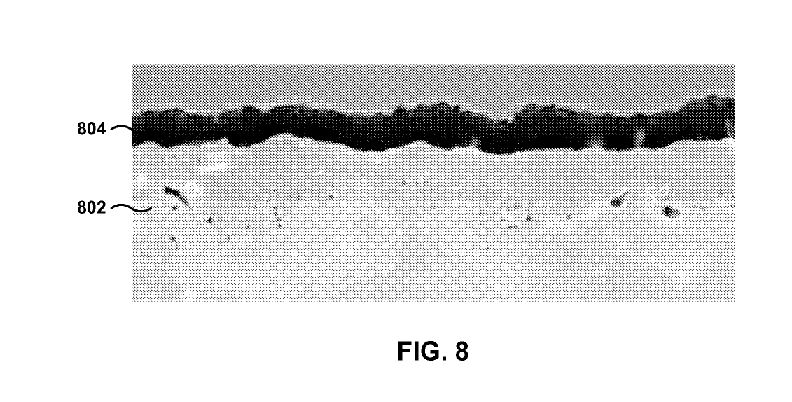

The coated substrate was then exposed to a cyclic oxidation test in air. The cyclic oxidation test included 100 one-hour cycles of heating to about 2100° F. The coating including the Pt- and Hf-modified γ-Ni+γ′-Ni₃Al phase constitution formed a thin, protective aluminum oxide scale 804 on the surface of the coating 802, as shown in FIG. 8.

Various embodiments of the invention have been described. These and other embodiments are within the scope of the following claims.

1. A method comprising:
depositing a Pt-group metal over a substrate;
heating within a closed retort the substrate and a composition comprising Al, a reactive element, and a halide activator to a sufficient temperature to form a vapor phase aluminum halide and a reactive element halide, wherein the Al comprises sufficient Al to form a coating comprising a γ-Ni+γ′-Ni₃Al phase constitution on the substrate, and wherein the composition is substantially free of filler;
depositing sufficient Al and reactive element over the substrate to form the coating comprising the γ-Ni+γ′-Ni₃Al phase constitution.

2. The method of claim 1, wherein depositing sufficient Al and reactive element over the substrate comprises depositing sufficient Al and reactive element over the substrate to form the coating consisting essentially of the γ-Ni+γ′-Ni₃Al phase constitution on the substrate.

3. The method of claim 1, wherein depositing sufficient Al and reactive element over the substrate comprises depositing sufficient Al and reactive element over the substrate to form the coating consisting of the γ-Ni+γ′-Ni₃Al phase constitution on the surface of the article.

4. The method of claim 1, wherein the Al source and the halide activator comprise an aluminum halogen compound.

5. The method of claim 1, wherein the Al source comprises at least one of elemental Al and an Al alloy, and wherein the halide activator comprises at least one of NH₄Cl, HCl, and (NH₄)HF₂.

6. The method of claim 1, wherein the reactive element comprises at least one of Hf, Y, Zr, La and Ce.

7. The method of claim 1, wherein the composition further comprises Si.

8. The method of claim 1, wherein the composition further comprises Cr.

9. The method of claim 1, wherein depositing the Pt-group metal over the substrate comprises depositing at least one of Pt, Pd, Ir, Rh, and Ru over the substrate.

10. The method of claim 1, further comprising heat-treating the substrate following depositing sufficient Al and reactive element over the substrate to form the coating comprising the γ-Ni+γ′-Ni₃Al phase constitution.

11. The method of claim 10, wherein heat-treating the substrate comprises heat-treating the substrate at a temperature of about 1000° C. to about 1200° C. for about 1 hour to about 5 hours.

12. The method of claim 11, wherein heat-treating the substrate comprises heat-treating the substrate at a temperature of about 1100° C. to about 1150° C. for about 1 hour to about 3 hours.

13. The method of claim 1, wherein heating within the closed retort the substrate and the composition comprising Al, the reactive element, and the halide activator comprises heating within the closed retort the substrate and the composition comprising Al, the reactive element, and the halide activator to a temperature of about 1400° F. to about 1800° F. for about 1 to about 20 hours.

14. The method of claim 13, wherein heating within the closed retort the substrate and the composition comprising Al, the reactive element, and the halide activator comprises heating within the closed retort the substrate and the composition comprising Al, the reactive element, and the halide activator to a temperature of about 1500° F. to about 1700° F. for about 1 hour to about 6 hours.

15. A method comprising:
depositing a Pt-group metal over a substrate;
heating within a closed retort the substrate and a first composition comprising Al to form a first vapor phase that deposits the Al over the substrate, wherein the first composition is substantially free of filler; and
heating within the closed retort the substrate and a second composition comprising a reactive element to form a second vapor phase that deposits the reactive element over the substrate, wherein the second composition is substantially free of filler, wherein an amount of Al and an amount of reactive element deposited on the substrate is sufficient to form a coating comprising a γ-Ni+γ′-Ni₃Al phase constitution.

16. The method of claim 15, wherein the amount of Al deposited on the substrate is sufficient to form the coating consisting essentially of the γ-Ni+γ′-Ni₃Al phase constitution.

17. The method of claim 15, wherein the amount of Al deposited on the substrate is sufficient to form the coating consisting of the γ-Ni+γ′-Ni₃Al phase constitution.

18. The method of claim 15, wherein heating within the closed retort the substrate and the first composition and heating within the closed retort the substrate and the second composition occur substantially simultaneously.

19. The method of claim 18, wherein the first composition further comprises a halide activator, and wherein the second composition further comprises the halide activator.

20. The method of claim 15, wherein heating within the closed retort the substrate and the first composition occurs sequentially with heating within the closed retort the substrate and the second composition.

21. The method of claim 20, wherein the first composition further comprises a first halide activator, and wherein the second composition further comprises an Al source and a second halide activator.

22. The method of claim 20, wherein the first composition further comprises the reactive element and a first halide activator, and wherein the second composition further comprises a second halide activator.

23. The method of claim 15, wherein depositing the Pt-group metal over the substrate comprises depositing at least one of Pt, Pd, Ir, Rh, and Ru over the substrate.

24. The method of claim 15, further comprising heat-treating the substrate following heating within the closed retort the substrate and the second composition.

25. The method of claim 24, wherein heat-treating the substrate comprises heat-treating the substrate at a temperature of about 1000° C. to about 1200° C. for about 1 hour to about 5 hours.

26. The method of claim 25, wherein heat-treating the substrate comprises heat-treating the substrate at a temperature of about 1100° C. to about 1150° C. for about 1 hour to about 3 hours.

27. The method of claim 15, wherein heating within the closed retort the substrate and the first composition comprising Al comprises heating within the closed retort the substrate and the first composition comprising Al to a temperature of about 1400° F. to about 1800° F. for about 1 to about 20 hours.

28. The method of claim 27, wherein heating within the closed retort the substrate and the first composition comprising Al comprises heating within the closed retort the substrate and the first composition comprising Al to a temperature of about 1500° F. to about 1700° F. for about 1 to about 6 hours.
